(19) United States
(12) Patent Application Publication
(10) Pub. No.: US 2026/0060108 A1
(43) Pub. Date: Feb. 26, 2026

(54) WIRING STRUCTURE AND SEMICONDUCTOR PACKAGE INCLUDING THE SAME

(71) Applicant: Samsung Electronics Co., Ltd., Suwon-si (KR)

(72) Inventors: DongWoon Park, Suwon-si (KR); Gyunghwan Oh, Suwon-si (KR)

(21) Appl. No.: 19/073,288

(22) Filed: Mar. 7, 2025

(30) Foreign Application Priority Data
Aug. 26, 2024 (KR) 10-2024-0114460

(51) Int. Cl. H01L 23/498; H01L 23/00; H01L 23/13; H01L 23/31; H01L 23/538; H01L 25/16; H10B 80/00; H10D 80/30

(52) U.S. Cl. CPC H01L 23/49838; H01L 23/13; H01L 23/49822; H01L 23/49894; H01L 23/5385; H01L 23/5386; H01L 25/16; H01L 23/3128; H01L 24/08; H01L 24/48; H01L 2224/08225; H01L 2224/48091; H01L 2224/48229; H01L 2225/0651; H01L 2225/06548; H01L 2924/1815; H10B 80/00; H10D 80/30

(57) ABSTRACT

The present disclosure as an embodiment is to provide a wiring structure including a first wiring pattern; an insulation layer covering at least a portion of the first wiring pattern; a second wiring pattern disposed on the insulation layer; a via penetrating at least a portion of the insulation layer and electrically connecting the first wiring pattern and the second wiring pattern; and a protruding pattern extending into the insulation layer and having at least a portion thereof embedded in the insulation layer, the protruding pattern disposed on the first wiring pattern and connected thereto, and positioned spaced apart from the via and surrounding at least a portion of the via on the first wiring pattern.

### CROSS-REFERENCE TO RELATED APPLICATION

This application claims priority to and the benefit of Korean Patent Application No. 10-2024-0114460 filed in the Korean Intellectual Property Office on Aug. 26, 2024, the entire contents of which are incorporated herein by reference.

### BACKGROUND OF THE DISCLOSURE

### (a) Field of the Disclosure

The present disclosure relates to a wiring structure and a semiconductor package including the same.

### (b) Description of the Related Art

A semiconductor package may be electrically connected to an external component through a wiring structure that includes an insulation layer and wiring patterns. The wiring structure may perform a function of redistributing a semiconductor chip and transmitting signals from the semiconductor chips to the outside. If delamination occurs between the insulation layer of the wiring structure and the wiring pattern, it may affect the reliability, performance, and lifespan of the semiconductor package.

### SUMMARY OF THE DISCLOSURE

The present disclosure, in one aspect, seeks to provide a wiring structure having improved adhesion strength between a wiring pattern and an insulation layer and a semiconductor package including the same.

The present disclosure, in another aspect, seeks to provide a wiring structure and a semiconductor package including the same capable of preventing a propagation of delamination between a wiring pattern and an insulation layer.

The present disclosure in one aspect provides a wiring structure including a first wiring pattern; an insulation layer covering at least a portion of the first wiring pattern; a second wiring pattern disposed on the insulation layer; a via penetrating at least a portion of the insulation layer and electrically connecting the first wiring pattern and the second wiring pattern; and a protruding pattern extending into the insulation layer and having at least a portion thereof embedded in the insulation layer, the protruding pattern disposed on the first wiring pattern and connected thereto, and position spaced apart from the via and surrounding at least a portion of the via on the first wiring pattern.

The present disclosure in another aspect provides a semiconductor package including a semiconductor chip; an encapsulant covering at least a portion of the semiconductor chip; and a first wiring structure disposed on the semiconductor chip and the encapsulant; wherein the first wiring structure includes a first wiring pattern; an insulation layer covering at least a portion of the first wiring pattern; a second wiring pattern disposed on the insulation layer; a via penetrating at least a portion of the insulation layer and electrically connecting the first wiring pattern and the second wiring pattern; and a protruding pattern having at least a portion embedded in the insulation layer, the protruding pattern disposed on the first wiring pattern and connected to the first wiring pattern, and positioned spaced apart from the via on the first wiring pattern.

The present disclosure as another an embodiment is to provide a semiconductor package including a first semiconductor package including a first wiring structure, a semiconductor chip disposed on the first wiring structure and connected to the first wiring structure, an encapsulant covering at least a portion of the semiconductor chip, and a second wiring structure disposed on the semiconductor chip and the encapsulant and connected to the first wiring structure; a second semiconductor package disposed on the second wiring structure; and a conductive bump disposed between the first semiconductor package and the second semiconductor package and connecting the first semiconductor package and the second semiconductor package, wherein the second wiring structure includes a first wiring pattern; an insulation layer covering at least a portion of the first wiring pattern; a second wiring pattern disposed on the insulation layer; a via penetrating at least a portion of the insulation layer and electrically connecting the first wiring pattern and the second wiring pattern; and a protruding pattern extending into the insulation layer and having at least a portion embedded in the insulation layer, the protruding pattern disposed on the first wiring pattern and connected to the first wiring pattern, and spaced apart from the via.

According to one aspect of the present disclosure, the wiring structure having improved adhesion strength between the wiring pattern and the insulation layer, and the semiconductor package including the same may be provided.

According to another aspect of the present disclosure, the wiring structure capable of preventing a propagation of delamination between the wiring pattern and the insulation layer, and the semiconductor package including the same may be provided.

### BRIEF DESCRIPTION OF THE DRAWINGS

FIG. 1 is a cross-sectional view of a wiring structure according to an embodiment.

FIG. 2 is a top view of a wiring structure according to an embodiment illustrated in FIG. 1.

FIG. 3 to FIG. 6 are views showing exemplary variations of a protruding pattern illustrated in FIG. 2.

FIG. 7 is a cross-sectional view of a wiring structure according to another embodiment.

FIG. 8 is a cross-sectional view of a semiconductor package according to an embodiment.

FIG. 9 is a cross-sectional view of a semiconductor package according to another embodiment.

FIG. 10 is a cross-sectional view of a semiconductor package according to another embodiment.

FIG. 11 is a cross-sectional view of a semiconductor package according to another embodiment.

FIG. 12 is a cross-sectional view of a semiconductor package of the package-on-package type according to an embodiment.

### DETAILED DESCRIPTION OF THE EMBODIMENTS

The present disclosure will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

In order to more clearly describe the present disclosure, a description of elements that are not related to the inventive concept may be omitted. Like reference numerals denote like elements throughout the drawings.

In addition, the size and thickness of each configuration shown in the drawings are arbitrarily shown for better understanding and ease of description, but the present disclosure is not limited thereto. In the drawings, the thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “connected to”, “coupled to”, or “on” another element, the element may be “directly connected to”, “directly coupled to”, or directly on the other element in which there are no intervening elements present at the point of contact, or “indirectly connected to”, “indirectly coupled to”, or “indirectly on” the other element through a third, intervening element. The term “contact,” “contacting,” “contacts,” or “in contact with,” as used herein, refers to a direct connection (i.e., touching at the point of contact) unless the context clearly indicates otherwise.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

In the specification, the word “on” or “above” means positioned on or below the object portion, and does not necessarily mean positioned on the upper side of the object portion based on a gravitational direction.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed. In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” or “in a plan view” means viewing a target portion from the top, and the phrase “on a cross-section” “a cross-sectional view” means viewing a cross-section formed by vertically cutting a target portion from the side.

Additionally, throughout the specification, ordinal numbers, such as a first, a second, etc., are used as labels to distinguish a component from other identical or similar components, and are not necessarily intended to refer to a specific component. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim. Thus, a component referred to as a first component in a particular part of this specification may be referred to as a second component in another part of this specification.

Additionally, throughout the specification, a singular reference to any component includes a plurality of references to that component, unless otherwise stated. For example, “an insulation layer” may be used to mean not only one insulation layer, but also a plurality of insulation layers, such as two, three or more.

Additionally, throughout the specification, references to directions such as an upper surface, an upper side, an upper part, a lower surface, a lower side, a lower part, etc. are provided with reference to the drawings to aid explanation and understanding.

Hereinafter, a wiring structure and a semiconductor package including the same according to embodiments of the present disclosure are described with reference to accompanying drawings.

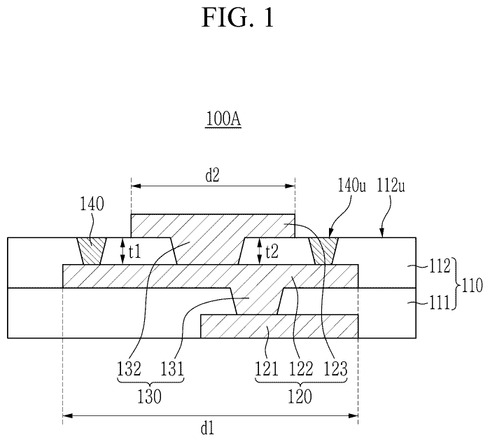

FIG. 1 is a cross-sectional view of a wiring structure according to an embodiment.

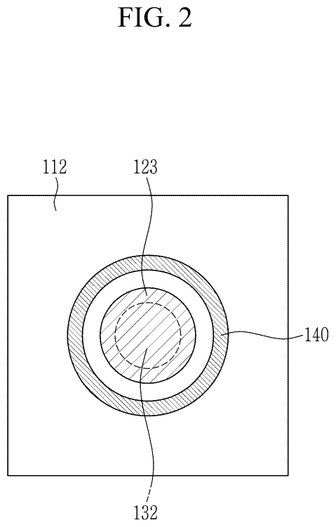

FIG. 2 is a top view of a wiring structure according to an embodiment illustrated in FIG. 1.

A wiring structure 100A may include insulation layers 110, wiring patterns 120, vias 130, and a protruding pattern 140. The insulation layers 110 may include a first insulation layer 111 and a second insulation layer 112 as shown in FIG. 1. The wiring patterns 120 may include a first wiring pattern 121, a second wiring pattern 122, and a third wiring pattern 123 as shown in FIG. 1. The vias 130 may include a first via 131 and a second via as shown in FIG. 1.

For example, the wiring structure 100A may include a first wiring pattern 121, a first insulation layer 111 covering at least a part of the first wiring pattern 121, a second wiring pattern 122 disposed on the first insulation layer 111, a second insulation layer 112 covering at least a part of the second wiring pattern 122, a third wiring pattern 123 disposed on the second insulation layer 112, a first via 131 penetrating through the first insulation layer 111 and electrically connecting the first wiring pattern 121 and the second wiring pattern 122, a second via 132 penetrating through the second insulation layer 112 and electrically connecting the second wiring pattern 122 and the third wiring pattern 123, and a protruding pattern 140 disposed on at least one wiring pattern such as second wiring pattern 122 among the wiring patterns 120.

The protruding pattern 140 may be a pattern that extends normal to the surface of a wiring pattern 120 to which the protruding pattern 140 is connected. The protruding pattern 140 may have a curved shape and may have an annular shape with a center aligned with a via 130 when viewed in a plan view. The protruding pattern 140 may surround the via 130 at the surface of the wiring pattern 120 to which the protruding pattern 140 is connected. The protruding pattern 140 may be a dummy pattern which does not transfer an electrical signal within the wiring structure 100A. In some embodiments, the protruding pattern 140 may be an annular dummy structure having annular dummy sub-patterns.

The number of the insulation layers 110, the wiring patterns 120, the vias 130, and the protruding patterns 140 included in the wiring structure 100A may vary depending on a design. For example, another insulation layer, another wiring pattern, and another via may be additionally placed below the first insulation layer 111 and the first wiring pattern 121.

In the following description, a generic one of the insulation layers 110, wiring patterns 120, or vias 130 may be referred to as an insulation layer 110, wiring pattern 120, or via 130, respectively. Each of the insulation layers 110 may cover at least a portion of a corresponding wiring pattern 120 of the wiring patterns 120. For example, the insulation layer 110 may cover the upper and side surfaces of the wiring pattern 120. The insulation layers 110 may be formed separately to cover a side surface of a wiring pattern and an upper surface of a wiring pattern. In some examples, a first portion of the first insulation layer 111 may be formed to be arranged at substantially the same level as the wiring pattern 120 and cover the side surface of the wiring pattern 120, and a second portion of the first insulation layer 111 may be formed on the wiring pattern 120 to cover the upper surface of the wiring pattern 120, and the two portions may be formed separately. The insulation layers 110 may have boundaries with each other that are apparent or may not have boundaries that can be seen with the naked eye, depending on the material and manufacturing process of the insulation layers 110.

The insulation layer 110 may include a photo-imageable dielectric (PID), which is a photosensitive insulating material. When the insulation layer 110 includes the PID, a fine pitch may be implemented through a photolithography process. However, other insulating materials, such as organic insulating materials such as epoxy (epoxy) or polyimide (PI) or inorganic insulating materials such as silicon oxide or silicon nitride, may be used as the material of the insulation layer 110.

Each of the wiring patterns 120 may be placed on a corresponding insulating layer of the insulation layer 110s and be electrically connected to another of the wiring patterns 120. The plurality of wiring patterns 120 may be arranged on the insulation layers 110 to form a wiring layer. The wiring patterns 120 may be connected to each other and function as a signal wiring that supplies signals, a power wiring that supplies a power, or a ground wiring that is grounded. In wiring structure 100A, there may be numerous wiring patterns 120 and vias 130 for connecting them, but the drawing only shows the configurations that may be placed adjacent to the protruding pattern 140.

The uppermost wiring pattern 120 (e.g., the third wiring pattern 123), which is located at the top of the wiring patterns 120, may be connected to a conductive bump such as a solder ball and may a function as a connection pad that provides an electrical connection between the wiring structure 100A and an external component. The uppermost wiring pattern 120 may include a plurality of metal layers. For example, the uppermost wiring pattern 120 may include a copper (Cu) layer as an electrical connection path, a nickel (Ni) layer to prevent diffusion and improve mechanical strength, and a gold (Au) layer to prevent oxidation and improve an electric characteristic.

The wiring pattern 120 in contact with the via 130 may function as a via pad for connection between the wiring pattern 120 and the via 130. The via pad (e.g., the wiring pattern functioning as the via pad) may be circular and may be formed with a diameter larger than the via 130 to provide a stable connection to the via 130. The via pad may be connected to a wiring trace, which is a wiring pattern that functions as an electrical path for transmitting signals, power, etc. The via pad and the wiring trace connected thereto may not have a boundary with each other (e.g., they may be formed as part of the same process).

The wiring pattern 120 may be formed of a conductive material, for example copper (Cu), aluminum (Al), silver (Ag), gold (Au), platinum (Pt), nickel (Ni), titanium (Ti), palladium (Pd) or an alloy thereof. Additionally, the wiring pattern 120 may include a plurality of layers. For example, the wiring pattern 120 may be formed by forming a seed layer, which is a thin film, by a physical vapor deposition (PVD) or a chemical vapor deposition (CVD), and then forming a plating layer through an electroplating on the seed layer.

The via 130 may penetrate at least a portion of the insulation layer 110 to connect the wiring patterns 120 positioned in different layers (e.g., the first via 131 may penetrate the insulation layer 110 to connect the first wiring pattern 121 and the second wiring pattern 122). The via 130 may be in contact with each of the wiring patterns 120 connected to the via 130.

The via 130, like the wiring pattern 120, may be formed of a conductive material, for example copper (Cu), aluminum (Al), silver (Ag), gold (Au), platinum (Pt), nickel (Ni), titanium (Ti), palladium (Pd) or an alloy thereof.

The via 130 may be formed by forming a via hole in an insulation layer of the insulation layer 110, forming a seed layer, which is a thin film, on the bottom and wall surfaces of the via hole by using a PVD or a CVD, and charging (filling) the inside of the via hole using electroplating. Depending on the processing method of the via hole, the via 130 may have a tapered shape with the width becoming narrower from one side to the other, a circular cylinder shape, etc. Additionally, the via 130 may be integrally formed with the wiring pattern 120 formed on the via 130, and there may be no boundary between them.

The protruding pattern 140 may be placed on a wiring pattern 120 among the wiring patterns 120, such as the second wiring pattern 122 as shown in FIG. 1, and connected to the wiring pattern 120 on which it is placed. At least a portion of the protruding pattern 140 may be embedded in the insulation layer 110 together with the wiring pattern 120 (e.g., the protruding pattern 140 may be connected to the second wiring pattern 122 and be embedded in the second insulation layer 112 together with the second wiring pattern 122. The protruding pattern 140 may be placed directly on the wiring pattern 120 and in contact with the wiring pattern 120.

The protruding pattern 140 may be spaced apart from the via 130, which is placed on the wiring pattern 120 together with the protruding pattern 140. The protruding pattern 140 may be positioned to surround at least a portion of the via 130. For example, the protruding pattern 140 may be a single protruding pattern 140 spaced apart from the via 130 and surrounding the entirety of the via 130 (referring to FIG. 2). The protruding pattern 140 is arranged to surround the via 130, so that a sufficient contact area and an adhesion strength may be secured between the protruding pattern 140 and the insulation layer 110.

In the wiring structure 100A, the protruding pattern 140 may be placed outside the wiring pattern 120 on which the protruding pattern 140 is connected (e.g., placed at a different level). With FIG. 1 as a reference, the protruding pattern 140 may be placed outside the second wiring pattern 122 on which the protruding pattern 140 is connected. For example, the protruding pattern 140 may be placed at a level between the second wiring pattern 122 and the third wiring pattern 123. Additionally, the protruding pattern 140 may be formed separately from the second wiring pattern 122 on which the protruding pattern 140 is connected and may have a boundary separating the protruding pattern from the second wiring pattern 122.

In an embodiment, the protruding pattern 140 may be located on the second wiring pattern 122 which is covered by the second insulation layer 112 and may extend into the uppermost of the insulation layers 110. In an embodiment, the protruding pattern 140 may be placed on the second wiring pattern 122 and connected to the second wiring pattern 122. Additionally, the protruding pattern 140 may be spaced from the second via 132 arranged on the second wiring pattern 122 and may surround at least a portion of the second via 132. The uppermost insulation layer 110 (e.g., the second insulation layer 112) may be placed at the outermost side and may be vulnerable to external impacts, etc., and may be separated from the wiring pattern 120 (e.g., the second wiring pattern 122)., The protruding pattern 140 may improve the adhesion strength between the insulation layer 110 and the wiring pattern 120 to reduce the likelihood of the uppermost insulating layer from being delaminated from the wiring pattern.

The protruding pattern 140 may be placed on the wiring pattern 120, which is closest to the uppermost of the wiring patterns 120. For example, in FIG. 1, the second wiring pattern 122 is closest to third wiring pattern 123, which is placed at the uppermost of the wiring patterns 120. The second wiring pattern 122 and the third wiring pattern 123 may be arranged in the layers closest to each other and be connected through the second via 132 that is in contact with each of them.

However, the protruding pattern 140 is not necessarily limited to being placed on the second wiring pattern 122 covered with the second insulation layer 112, and the protruding pattern 140 may be placed on any of the wiring patterns 120 where peeling from the insulation layer 110 is likely to occur without any limitation in a position.

The protruding pattern 140, like the wiring pattern 120 and the via 130, may be formed of a conductive material, for example copper (Cu), aluminum (Al), silver (Ag), gold (Au), platinum (Pt), nickel (Ni), titanium (Ti), palladium (Pd) or an alloy thereof.

The protruding pattern 140 may be formed by forming a hole in the insulation layer 110, similar to the via 130, forming a seed layer as a thin film on the bottom and wall surfaces of the hole by using PVD or CVD, and filling the inside of the hole using an electroplating. The wiring pattern 120 may be exposed at the bottom surface of the hole, and the insulation layer 110 may form the wall of the hole. Depending on the processing method for forming the hole, the protruding pattern 140 may have a tapered shape that becomes narrower from one end to an opposite end, a circular cylinder shape, etc.

The thickness of the protruding pattern 140 may be less than or equal to the thickness t2 of the via 130 which the protruding pattern surrounds (e.g., in FIG. 1 the thickness of the protruding pattern 140 is less than or equal to the thickness t2 of the second via 132). In an embodiment, the protruding pattern 140 may be formed together with the via 130 which the protruding pattern surrounds (e.g., the second via 132), and the thickness t1 of the protruding pattern 140 may be substantially the same as the thickness t2 of the via 130 which the protruding pattern surrounds (e.g., the second via 132). Additionally, the upper and lower surfaces of the protruding pattern 140 may be positioned at substantially the same level as the upper and lower surfaces of the via 130 which the protruding pattern surrounds (e.g., the second via 132), respectively.

In order to secure a space for forming the protruding pattern 140, the diameter d1 of the wiring pattern 120 on which the protruding pattern 140 is placed (e.g., the second wiring pattern 122) may be formed to be relatively large. For example, the diameter d1 of the wiring pattern 120 on which the protruding pattern 140 is placed (e.g., the second wiring pattern 122) may be larger than the diameter d2 of the wiring pattern 120 placed on the wiring pattern 120 (e.g., the third wiring pattern 123 placed on the second wiring pattern 122). The wiring patterns 120 may be via pads that are electrically connected by being in contact with the via 130 (e.g., the second wiring pattern 122 and the third wiring pattern 123 may be via pads electrically connected by the second via 132).

The upper surface 140u of the protruding pattern 140 may be exposed with respect to the upper surface of the insulation layer 110 in which the protruding pattern 140 is embedded (e.g., upper surface 112u of the second insulation layer 112). The upper surface 140u of the protruding pattern 140 may not be electrically connected to other elements such as other wire patterns. For example, the protruding pattern 140 may be misaligned vertically with the wiring pattern 120 on the insulation layer 110 (e.g., the third wiring pattern on the second insulation layer 112) and may not be connected to the wiring pattern 120 on the insulation layer 110. To prevent electric shorts, the upper surface 140u of the protruding pattern 140 may be covered with an insulating material such as a passivation layer 150 described below.

The side of the protruding pattern 140 may be covered by the insulation layer 110 in which the protruding pattern 140 is embedded (e.g., the second insulation layer 112 in FIG. 1). Additionally, the lower surface of the protruding pattern 140 may be in contact with the wiring pattern 120 on which the protruding pattern 140 is connected (e.g., the second wiring pattern 122).

Conductive bumps may be placed on the wiring structure for the electrical connection between the wiring structure and external components. The conductive bump may be placed on the connection pad (an outermost wiring pattern such as third wiring pattern 123) of the wiring structure and covered by an underfill material. If a coefficient of a thermal expansion (CTE) of the underfill material is greater than the CTE of the conductive bump, there is an increased risk of delamination between the insulation layer (e.g., the outermost insulation layer) and the wiring pattern embedded therein due to a strong shrinkage and expansion of the underfill material during a thermal cycle. Additionally, due to the shrinkage and expansion of the conductive bump during the thermal cycle, there is an increased risk of delamination between the wiring patterns and insulation layer connected thereto. Delamination due to the shrinkage and expansion of the conductive bump may be more noticeable when using a conductive bump with high mechanical strength. If delamination were to occur between the insulation layer of the wiring structure and the wiring pattern, it may affect the reliability, performance, and lifespan of the semiconductor package.

According to the present disclosure, by introducing the protruding pattern 140 on the wiring pattern 120, the contact area between the insulation layer 110 and the patterns 120 and 140 embedded therein may be increased, thereby improving the adhesion strength therebetween. In addition, even if a local delamination occurs between the insulation layer 110 and the wiring pattern 120, propagation of the delamination may be prevented by the protruding pattern 140. When the insulation layer 110 includes PID, both fine pitch implementation and adhesion with the wiring pattern 120 may be achieved by introducing the protruding pattern 140.

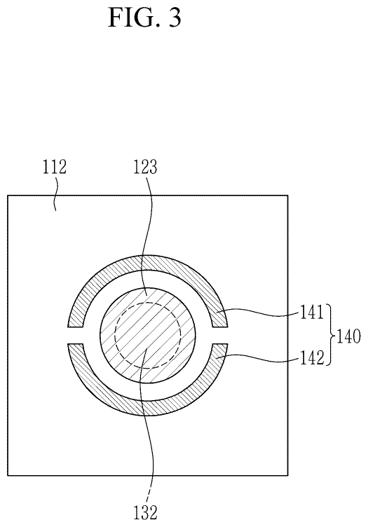

FIG. 3 to FIG. 6 views showing exemplary variations of a protruding pattern illustrated in FIG. 2.

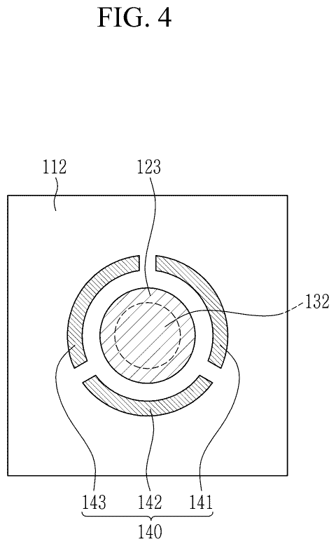

Referring to FIG. 3 and FIG. 4, each of protruding patterns 140 may include a plurality of protruding sub-patterns surrounding a portion of a second via 132. For example, the protruding pattern 140 may include a first protruding sub-pattern 141 surrounding a portion of the second via 132 and a second protruding sub-pattern 142 surrounding another portion of the second via 132, spaced apart from the first protruding sub-pattern 141 (referring to FIG. 3). If desired, the protruding pattern 140 may further include a third protruding sub-pattern 143 that surrounds another part of the second via 132, spaced apart from the first protruding sub-pattern 141 and the second protruding sub-pattern 142 (referring to FIG. 4). An imaginary line connecting the plurality of protruding sub-patterns may surround the second via 132, forming a roughly circular shape. By forming the plurality of protruding sub-patterns spaced apart from each other, a photolithography process may be performed using one mask when forming the protruding pattern 140.

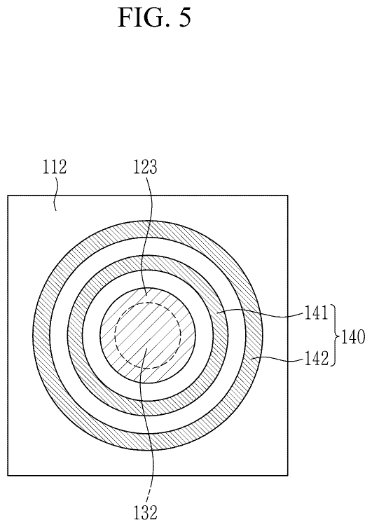

Referring to FIG. 5, the protruding pattern 140 may include a plurality of protruding sub-patterns spaced apart in a radial direction extending away from the second via 132. For example, each of the protruding sub-patterns may surround the entire second via 132 and the protruding pattern 140 may include a first protruding sub-pattern 141 and a second protruding sub-pattern 142 which are spaced in a radial direction extending away from the second via 132. By forming the multiple protruding sub-patterns in a radial direction extending away from second via 132, the contact area between the protruding pattern 140 and the insulation layer 110 may be further increased, and the propagation of a delamination may be prevented more efficiently.

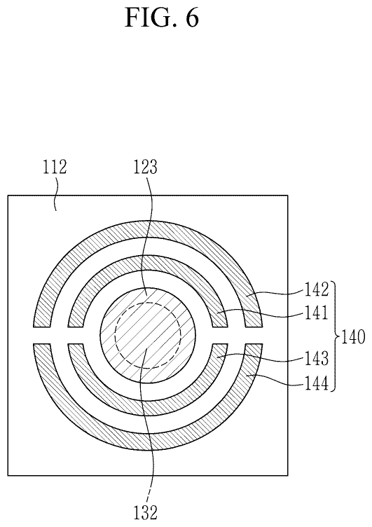

Referring to FIG. 6, the protruding pattern 140 includes protruding sub-patterns that each surround a portion of the second via 132 and the plurality of protruding patterns 140 are spaced apart in a radial direction extending away from the second via 132. For example, the protruding pattern 140 may include a first protruding sub-pattern 141 and a second protruding sub-pattern 142, each surrounding a portion of the second via 132 and spaced apart from one another in a radial direction extending away from the second via 132, and a third protruding sub-pattern 143 and a fourth protruding sub-pattern 144, each surrounding a different portion of the second via 132 and spaced apart from one another in a direction radial direction extending away from the second via 132.

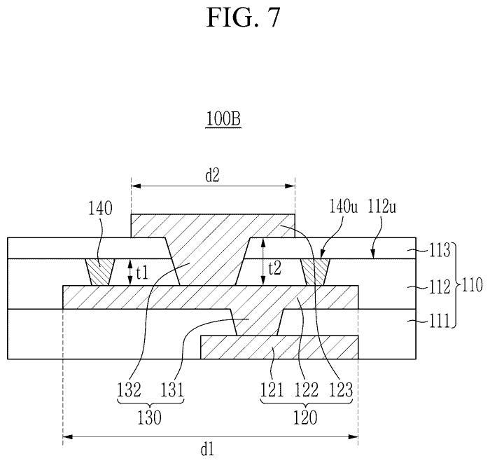

FIG. 7 is a cross-sectional view of a wiring structure according to another embodiment.

In another embodiment, an upper surface 140u of a protruding pattern 140 may be covered by an insulation layer 110. The wiring structure 100B may further include a third insulation layer 113, which is an additional insulation layer covering the protruding pattern 140. The third insulation layer 113 may be placed on the second insulation layer 112, and the upper surface 140u of the protruding pattern 140 may be exposed with respect to the upper surface 112u of the second insulation layer 112 and be covered by the third insulation layer 113.

The third wiring pattern 123 may be placed on the third insulation layer 113, and the second via 132 connected to the third wiring pattern 123 may penetrate through the second insulation layer 112 and the third insulation layer 113. Depending on the manufacturing method of the second via 132, the region of the second via 132 penetrating the second insulation layer 112 and the region of the second via 132 penetrating the third insulation layer 113 may have boundaries from each other, or they may be integrated (e.g., formed as part of the same process).

The thickness t1 of the protruding pattern 140 may be less than the thickness t2 of the via 130 that the protruding pattern 140 surrounds (e.g., the second via 132). The lower surface of the protruding pattern 140 may be positioned at substantially the same level or the same level as the lower surface of the via 130 that the protruding pattern 140 surrounds (e.g., the second via 132), and the upper surface of the protruding pattern 140 may be positioned at a level lower than the upper surface of the second via 130.

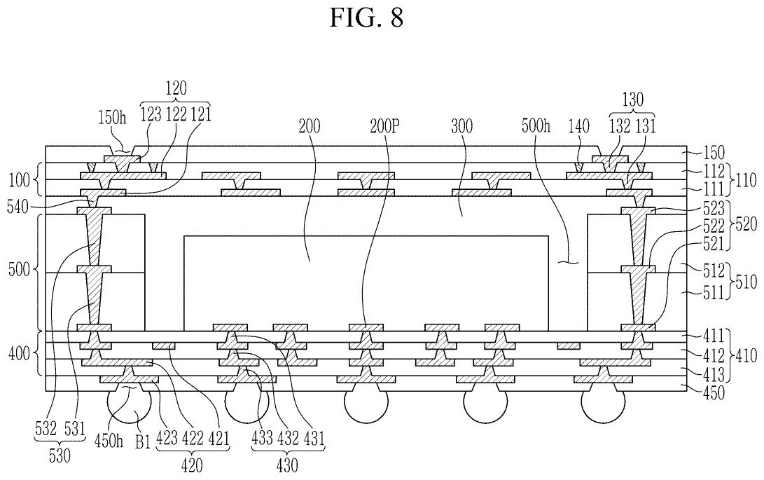

FIG. 8 is a cross-sectional view of a semiconductor package according to an embodiment.

A semiconductor package may include a first wiring structure 100, a semiconductor chip 200, an encapsulant 300, a second wiring structure 400, and a core substrate 500.

The first wiring structure 100 may be placed on the upper side of the semiconductor chip 200 and the encapsulant 300, and the semiconductor package may be electrically connected to another component (e.g., another semiconductor package) placed on the upper side thereof. The first wiring structure 100 may be spaced apart from the second wiring structure 400 with the semiconductor chip 200 and the encapsulant 300 interposed therebetween, and be connected to the second wiring structure 400 through the core substrate 500.

The first wiring structure 100 may include a protruding pattern 140 according to the present disclosure, and may be any one of wiring structures 100A and 100B according to an embodiment. The above-mentioned contents in the description of FIG. 1 to FIG. 7 may be equally applied to the description for the first wiring structure 100 and the components (the insulation layer 110, the wiring pattern 120, the via 130, and the protruding pattern 140) included therein.

The passivation layer 150 may be placed on the first wiring structure 100.

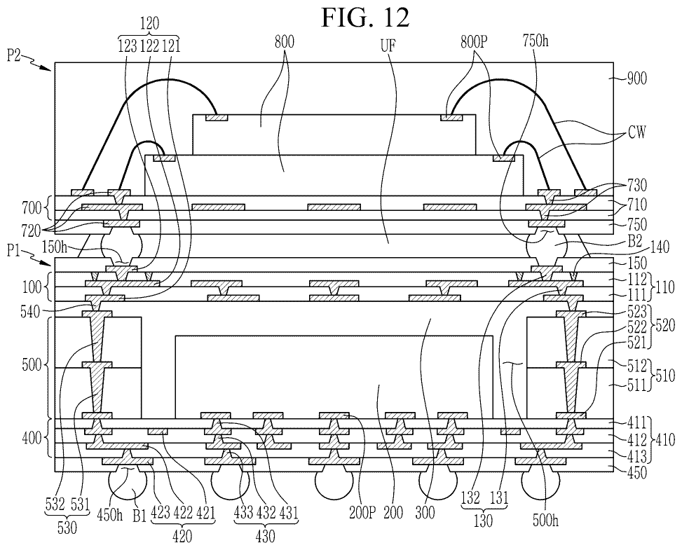

The passivation layer 150 may be placed on the first wiring structure 100 and serve to protect the first wiring structure 100. An insulating material such as a solder resist may be used as the material for the passivation layer 150. The passivation layer 150 may have an opening 150h that exposes at least a portion of a third wiring pattern 123 that functions as a connection pad. A conductive bump (B2, referring to FIG. 12) may be placed in the opening 150h to connect the semiconductor package to other components.

The semiconductor chip 200 may be placed on the second wiring structure 400 and connected to the second wiring structure 400. The semiconductor chip 200 may have a connection pad 200P, and may be arranged in a face down orientation so the connection pad 200P faces the second wiring structure 400, or may be arranged in a face up orientation so the connection pad 200P faces the first wiring structure 100. The semiconductor chip 200 may be connected through contact with the second wiring structure 400, or may be connected through other configurations such as conductive bumps and conductive wires.

The type of the semiconductor chip 200 is not particularly limited.

For example, the semiconductor chip 200 may include a logic chip. The logic chip may include one or more of an application processor (AP), a microprocessor, a central processing unit (CPU), a graphic processing unit (GPU), a neural processing unit (NPU), an application specific integrated circuit (ASIC), and a system on chip (SoC).

Alternatively, the semiconductor chip 200 may include a memory chip. The memory chip may include one or more of a dynamic random access memory (DRAM) chip, a static random access memory (SRAM) chip, a flash memory chip, a high bandwidth memory (HBM) chip, a read-only memory (ROM) chip, and a magnetic random access memory (MRAM) chip.

The semiconductor chip 200 may be one of a plurality of semiconductor chips 200.

The encapsulant 300 may cover at least a portion of the semiconductor chip 200. Additionally, the encapsulant 300 may fill at least a portion of the penetration hole 500h of the core substrate 500 and extend onto the core substrate 500. An insulating material such as epoxy molding compound (EMC) may be used as the material for the encapsulant 300.

The second wiring structure 400 may be arranged on the lower side of the semiconductor chip 200 and the encapsulant 300, and be connected to each of the semiconductor chip 200 and the core substrate 500.

The second wiring structure 400 may include insulation layers 410, wiring patterns 420, and vias 430.

For example, the second wiring structure 400 may include a first insulation layer 411, a first wiring pattern 421 disposed on the first insulation layer 411, a second insulation layer 412 covering at least a part of the first wiring pattern 421, a second wiring pattern 422 disposed on the second insulation layer 412, a third insulation layer 413 covering at least a part of the second wiring pattern 422, a third wiring pattern 423 disposed on the third insulation layer 413, a first via 431 penetrating at least a portion of the first insulation layer 411 and electrically connecting the semiconductor chip 200 and the first wiring pattern 421 or the semiconductor chip 200 and the core substrate 500, a second via 432 penetrating at least a portion of the second insulation layer 412 and electrically connecting the first wiring pattern 421 and the second wiring pattern 422 by, and a third via 433 penetrating at least a portion of the third insulation layer 413 and electrically connecting the second wiring pattern 422 and the third wiring pattern 423.

Each insulation layer 410 may cover at least a portion of the wiring pattern 420. For example, the insulation layer 410 may cover the bottom and side surfaces of the wiring pattern 420. If necessary, an insulation layer 410 disposed at substantially the same level as the wiring pattern 420 and covering the side surface of the wiring pattern 420 and an insulation layer disposed on the wiring pattern 420 and covering the lower surface of the wiring pattern 420 may be formed separately. The insulation layers 410 may have discernable boundaries with each other or may not have boundaries that can be seen with the naked eye, depending on the material and the manufacturing process of the insulation layers 410.

The insulation layer 410 may include PID, a photosensitivity insulating material. If the insulation layer 410 includes the PID, a fine pitch may be implemented through the photolithography process. However, other insulating materials, such as organic insulating materials such as epoxy (epoxy) or polyimide (PI) or inorganic insulating materials such as silicon oxide or silicon nitride, may be used as the material of the insulation layer 410.

Each wiring pattern 420 may be placed on the insulation layer 410 and be electrically connected to another wiring pattern 420. A plurality of wiring patterns 420 may be arranged on the insulation layer 410 to form a wiring layer. The wiring patterns 420 may be connected to each other and function as a signal wiring that supplies signals, a power wiring that supplies power, or a ground wiring that provides a ground.

The third wiring pattern 423, which is located at the lowermost of the wiring patterns 420, may be connected to the conductive bump B1 and perform a function of a connection pad that provides an electrical connection between the second wiring structure 400 and an external component (e.g., a substrate).

The wiring pattern 420 may be formed of a conductive material, for example copper (Cu), aluminum (Al), silver (Ag), gold (Au), platinum (Pt), nickel (Ni), titanium (Ti), palladium (Pd) or an alloy thereof. Additionally, the wiring pattern 420 may consist of a plurality of layers. For example, the wiring pattern 420 may be formed by forming a seed layer as a thin film by a PVD or a CVD, and then forming a plating layer through an electroplating on the seed layer.

The via 430 may penetrate at least a portion of the insulation layer 410 to connect the wiring patterns 420 positioned in different layers. The via 430 may be in contact with each of the wiring patterns 420 that are connected to the via 430.

The via 430, like the wiring pattern 420, may be formed of a conductive material, for example copper (Cu), aluminum (Al), silver (Ag), gold (Au), platinum (Pt), nickel (Ni), titanium (Ti), palladium (Pd) or an alloy thereof.

The via 430 may be formed by forming a via hole in the insulation layer 410, forming a seed layer as a thin film on the bottom and wall surfaces of the via hole by a PVD or a CVD, and filling the inside of the via hole by electroplating. Depending on the processing method of the via hole, the via 430 may have a taper shape that becomes narrower from one end to the other, a circular cylinder shape, etc. Additionally, the via 430 may be integrally formed with the wiring pattern 420 disposed on the lower side of the via 430, and there may be no boundary between them.

A passivation layer 450 and a conductive bump B1 may be placed on the second wiring structure 400.

The passivation layer 450 may be arranged on the second wiring structure 400 to protect the second wiring structure 400. An insulating material such as a solder resist may be used as the material for the passivation layer 450. The passivation layer 450 may have an opening 450h that exposes at least a portion of the third wiring pattern 123 that functions as a connection pad.

The conductive bump B1 may be arranged on the passivation layer 450 to fill the opening 450h and be connected to the third wiring pattern 123. The conductive bump B1 may be directly connected by being in contact with, for example, the third wiring pattern 123. If necessary, an under bump metallurgy (UBM) may be placed between the conductive bump B1 and the third wiring pattern 123.

A conductive material such as a solder may be used as the material for conductive bump B1. The conductive bump B1 may have a shape such as a ball or pillar. Additionally, the number, spacing, arrangement, etc. of the conductive bumps B1 may be implemented in various ways.

The core substrate 500 may be placed on the second wiring structure 400 and connect the first wiring structure 100 and the second wiring structure 400.

The core substrate 500 may have a penetration hole 500h. The penetration hole 500h penetrates through the core substrate 500 between the upper and lower surfaces of the core substrate 500, and the semiconductor chip 200 may be placed within the penetration hole 500h.

The core substrate 500 may include an insulation layer(s) 510, a wiring pattern(s) 520, and a via(s) 530. For example, the core substrate 500 may include a first wiring pattern 521, a first insulation layer 511 covering the first wiring pattern 521, a second wiring pattern 522 disposed on the first insulation layer 511, a second insulation layer 512 placed on the first insulation layer 511 and covering the second wiring pattern 522, a third wiring pattern 523 placed on the second insulation layer 512, a first via 531 penetrating through the first insulation layer 511 and electrically connecting the first wiring pattern 521 and the second wiring pattern 522, and a second via 532 penetrating through the second insulation layer 512 and electrically connecting the second wiring pattern 522 and the third wiring pattern 523.

Each insulation layer 510 may cover at least a portion of the wiring pattern 520. For example, the insulation layer 510 may cover the top and side surfaces of the wiring pattern 520. As the material of the insulation layer 510, an insulating material may be used, for example, epoxy (epoxy), polyimide (PI), prepreg (prepreg), etc. can be used.

The wiring pattern 520 may electrically connect the first wiring structure 100 and the second wiring structure 400. Each wiring pattern 520 may be placed on the insulation layer 510 and be electrically connected to another wiring pattern 520. A plurality of wiring patterns 520 may be arranged on the insulation layer 510 to form a wiring layer. The wiring patterns 520 may connected to each other and function as a signal wiring that supplies signals, a power wiring that supplies a power, or a ground wiring that provides a ground.

The wiring pattern 520 may be formed of a conductive material, for example copper (Cu), aluminum (Al), silver (Ag), gold (Au), platinum (Pt), nickel (Ni), titanium (Ti), palladium (Pd) or an alloy thereof. Additionally, the wiring pattern 520 may consist of a plurality of layers. For example, the wiring pattern 520 may be formed by forming a seed layer as a thin film by a PVD or a CVD, and then forming a plating layer through an electroplating on the seed layer.

The via 530 may penetrate at least a portion of the insulation layer 510 to connect wiring patterns 520 positioned in different layers. The via 530 may be in contact with each of the wiring patterns 520 connected to the via 530.

The via 530, like the wiring pattern 520, may be formed of a conductive material, for example copper (Cu), aluminum (Al), silver (Ag), gold (Au), platinum (Pt), nickel (Ni), titanium (Ti), palladium (Pd) or an alloy thereof.

The via 530 may be formed by forming a via hole in the insulation layer 510, forming a seed layer as a thin film on the bottom and wall surfaces of the via hole using a PVD or a CVD, and filling the inside of the via hole using electroplating. Depending on the processing method of the via hole, via 530 may have a taper shape that becomes narrower from one end to the other, a circular cylinder shape, an hourglass shape, etc. Additionally, the via 530 may be integrally formed with the wiring pattern 520 arranged on the upper side of via 530, and there may be no apparent boundary between them.

The semiconductor package may further include a connection via 540 for connecting the first wiring structure 100 and the core substrate 500. The connection via 540 may pass through a portion of the encapsulant 300 to connect the wiring pattern 520 of the first wiring structure 100 and the wiring pattern 520 of the core substrate 500. The description for the connection via 540 may apply equally the description for the via 530, unless otherwise specifically contradicted.

In some embodiments, the second wiring structure 400 may be placed directly on the lower surface of the core substrate 500 and be connected by being in contact with each other.

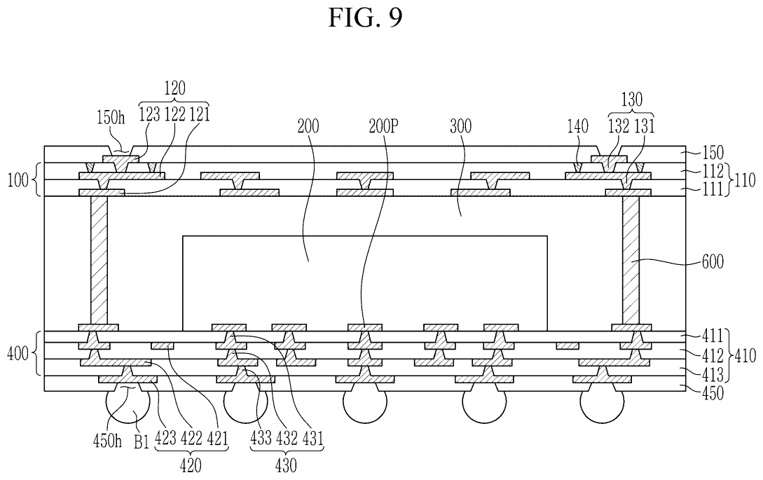

FIG. 9 is a cross-sectional view of a semiconductor package according to another embodiment.

The first wiring structure 100 and the second wiring structure 400 may be connected by a conductive post 600 which may replace the core substrate 500 shown in FIG. 8. The conductive post 600 may be embedded in the encapsulant 300. The material for the conductive post 600 may be a conductive material such as copper (Cu) or aluminum (Al). According to an embodiment, the conductive post 600 may be connected to the first wiring pattern 121 via a connecting via (referring to a connecting via 540 in FIG. 8) that penetrates a portion of the encapsulant 300.

For other configurations of the semiconductor package, the same provisions as those described elsewhere in this specification may be applied unless otherwise specifically contradicted.

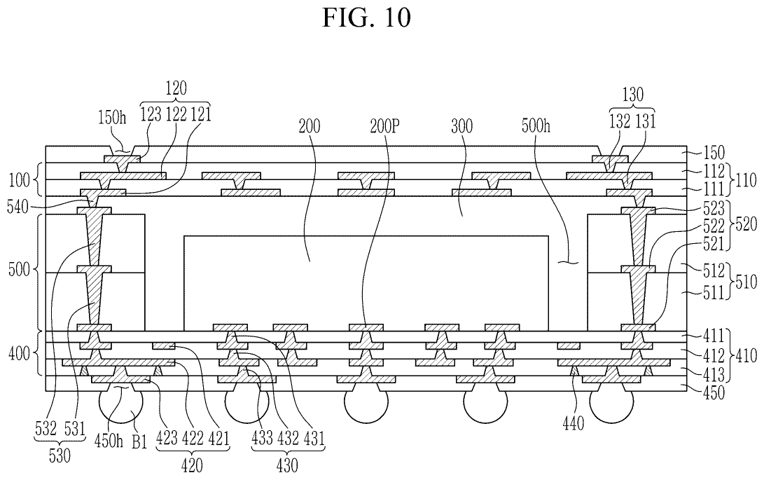

FIG. 10 is a cross-sectional view of a semiconductor package according to another embodiment.

In the semiconductor package, a protruding pattern 440 may be included in a second wiring structure 400. The description of the protruding pattern 440 is equally applicable to the description of the protruding pattern 140, unless otherwise specifically contradicted.

In an embodiment, the protruding pattern 440 may be placed on a second wiring pattern 422 covered by a third insulation layer 413 placed on the lowermost (outermost) side of the insulation layers 410. In an embodiment, the protruding pattern 440 may be placed on the second wiring pattern 422 and connected to the second wiring pattern 422. Additionally, the protruding pattern 440 may be spaced from the third via 433 arranged on the second wiring pattern 422 and may surround at least a portion of the third via 433. The lowermost insulation layer (e.g., the third insulation layer 413) is placed at the outermost side and is vulnerable to external impacts, etc., and risks being peeled off from the wiring pattern (e.g., the second wiring pattern 422). Therefore, improvement of the adhesion strength between the lowermost insulation layer (e.g., the third insulation layer) 413 and the wiring pattern (e.g., the second wiring pattern 422) through the introduction of the protruding pattern 440 may be beneficial.

The protruding pattern 440 may also be placed on the second wiring pattern 422, which is closest to the third wiring pattern 423, which is placed at the bottom of the wiring patterns 420. The second wiring pattern 422 and the third wiring pattern 423 may be arranged in the layers closest to each other and be connected through the third via 433 that is each contact with them.

In FIG. 10, the first wiring structure 100 is depicted as not including the protruding pattern 140, but both the first wiring structure 100 and the second wiring structure 400 may include the protruding patterns 140 and 440.

For other configurations of the semiconductor package, the same provisions as those described elsewhere in this specification may be applied unless otherwise specifically contradicted.

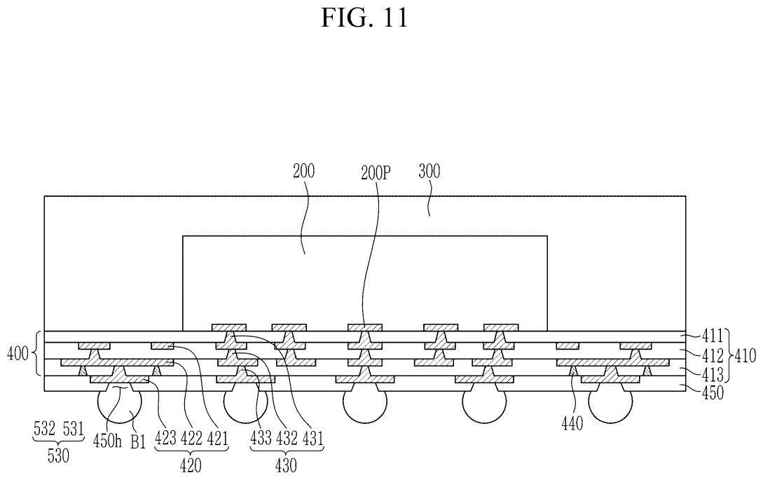

FIG. 11 is a cross-sectional view of a semiconductor package according to another embodiment.

The semiconductor package may not include a first wiring structure 100 and a core substrate 500 for the connection to an external component arranged thereon, and a protruding pattern 440 may be included in a second wiring structure 400. A semiconductor package may be a configuration placed on another configuration, such as a substrate or another semiconductor package.

For other configurations of the semiconductor package, the same provisions as those described elsewhere in this specification may be applied unless specifically contradicted.

FIG. 12 is a cross-sectional view of a semiconductor package of a package-on-package type according to an embodiment.

The semiconductor package may include a first semiconductor package P1 and a second semiconductor package P2 arranged on the first semiconductor package P1. The first semiconductor package P1 and the second semiconductor package P2 may be connected through a conductive bump B2 placed between them.

The first semiconductor package P1 may include a first wiring structure 100 including a protruding pattern 140 according to the present disclosure. For example, the first semiconductor package P1 may be any one of the semiconductor packages illustrated in FIG. 8 to FIG. 11. If desired, the wiring structure 700 of the second semiconductor package P2 may also include a protruding pattern according to the present disclosure (the wiring structure 700 may be similar to the second wiring structure 400 illustrated in FIG. 11).

In an embodiment, the semiconductor package may be a semiconductor package of a package-on-package type in which a memory package is stacked on an application processor (AP) package. For example, the first semiconductor package may include an AP package, and the second semiconductor package P2 may include a memory package.

The second semiconductor package P2 may be placed on the second wiring structure 400.

The second semiconductor package P2 may include a wiring structure 700, a semiconductor chip(s) 800, and an encapsulant 900.

The wiring structure 700 may include an insulation layer(s) 710, a wiring pattern(s) 720, and a via(s) 730. If necessary, the wiring structure 700 of the second semiconductor package P2 may also include a protruding pattern according to the present disclosure. The protruding pattern may be at least partially embedded in the insulation layer 710, disposed on at least one of the wiring patterns 720, connected to the wiring pattern 720, and spaced from the via 730, a surround at least a portion of the via 730.

The semiconductor chip 800 may be placed on the wiring structure 700 and connected to the wiring structure 700. The semiconductor chip 800 may have a connection pad 800P, and the connection pad 800P may be connected to the wiring structure 700 via, for example, a conductive wire CW.

The encapsulant 900 may cover at least a portion of the semiconductor chip 800. An insulating material such as an epoxy molding compound (EMC) may be used as the material for the encapsulant 900.

A passivation layer 750 and a conductive bump B2 may be placed on the wiring structure 700.

The passivation layer 750 may be placed on the wiring structure 700 and serve to protect the wiring structure 700. An insulating material such as a solder resist may be used as the material for the passivation layer 750. The passivation layer 750 may have an opening 750h that exposes at least a portion of the lowermost wiring pattern 720 that functions as a connecting pad.

The conductive bump B2 may be placed on the passivation layer 750 to fill the opening 750h and be connected to the lowermost wiring pattern 720. Additionally, the conductive bump B2 may be arranged on the first semiconductor package P1 to fill the opening 150h of the passivation layer 150 and be connected to the uppermost wiring pattern 120 (e.g., the third wiring pattern 123) of the first wiring structure 100. The conductive bump B2 may be directly connected by being in contact with, for example, the uppermost wiring pattern (e.g., the third wiring pattern 123).

A conductive material such as a solder may be used as the material for the conductive bump B2. The conductive bump B2 may have a shape of a ball, a filler, etc. Additionally, the number, spacing, arrangement, etc. of the conductive bumps B2 may be implemented in various ways.

The conductive bump B2 may be covered by an underfill material (UF) between the first semiconductor package P1 and the second semiconductor package P2.

In a semiconductor package of the package-on-package type that does not include embodiments of the inventive concept, a delamination may frequently occur between an insulation layer and a wiring pattern in the wiring structure connected to the upper package of the lower package. For example, if the CTE of the underfill material (UF) is greater than the CTE of the conductive bump, delamination may occur between the insulation layer (e.g., the outermost insulation layer) and the wiring pattern embedded therein due to the strong shrinkage and expansion of the underfill material (UF) during the thermal cycle. Additionally, due to the shrinkage and expansion of the conductive bump during the thermal cycle, the delamination may occur between the wiring patterns connected thereto and the insulation layer. The delamination due to the shrinkage and expansion of the conductive bump may be more noticeable when using a conductive bump with high mechanical strength.

According to the present disclosure, by introducing the protruding pattern 140 on the wiring pattern 120, the contact area between the insulation layer 110 and the patterns 120 and 140 embedded therein may be increased, thereby improving the adhesion strength therebetween. In addition, even if local delamination occurs between the insulation layer 110 and the wiring pattern 120, the propagation of the delamination may be prevented by the protruding pattern 140.

While this disclosure has been described in connection with exemplary embodiments, it is to be understood that the inventive concept is not limited to the described embodiments, but, on the contrary, is intended to cover various modifications and equivalent arrangements included within the spirit and scope of the appended claims.

Additionally, the embodiments in the present disclosure are not necessarily independent of each other and may be implemented in combination with each other unless specifically contradictory. Therefore, combined embodiments of the present disclosure should also be considered as included in the inventive concept.

What is claimed is:

1. A wiring structure comprising:
a first wiring pattern;
an insulation layer covering at least a portion of the first wiring pattern;
a second wiring pattern disposed on the insulation layer;
a via penetrating at least a portion of the insulation layer and electrically connecting the first wiring pattern and the second wiring pattern; and
a protruding pattern extending into the insulation layer and having at least a portion thereof embedded in the insulation layer, the protruding pattern disposed on the first wiring pattern and connected thereto, and positioned spaced apart from the via and surrounding at least a portion of the via on the first wiring pattern.

2. The wiring structure of claim 1, wherein:
the protruding pattern includes a plurality of protruding sub-patterns, each of which surrounds a portion of the via.

3. The wiring structure of claim 1, wherein:
the protruding pattern includes plurality of protruding sub-patterns that are each spaced apart from one another in a radial direction extending away from the via.

4. The wiring structure of claim 1, wherein:
an upper surface of the protruding pattern is exposed with respect to an upper surface of the insulation layer.

5. The wiring structure of claim 1, wherein:
an upper surface of the protruding pattern is covered by the insulation layer.

6. The wiring structure of claim 5, wherein:
the insulation layer is a first insulation layer of a plurality of insulation layers including the first insulation layer and a second insulation layer disposed on the first insulation layer, and
the upper surface of the protruding pattern is exposed with respect to an upper surface of the first insulation layer and covered by the second insulation layer.

7. The wiring structure of claim 1, wherein:
a thickness of the protruding pattern is less than or equal to a thickness of the via.

8. The wiring structure of claim 1, wherein:
the protruding pattern is in contact with the first wiring pattern.

9. The wiring structure of claim 1, wherein:
a diameter of the first wiring pattern is larger than a diameter of the second wiring pattern.

10. The wiring structure of claim 1, wherein:
the protruding pattern is not electrically connected to the second wiring pattern.

11. The wiring structure of claim 1, wherein:
the insulation layer includes a photo-imageable dielectric (PID).

12. A semiconductor package comprising:
a semiconductor chip;
an encapsulant covering at least a portion of the semiconductor chip; and
a first wiring structure disposed on the semiconductor chip and the encapsulant;
wherein the first wiring structure includes
a first wiring pattern;
an insulation layer covering at least a portion of the first wiring pattern;
a second wiring pattern disposed on the insulation layer;
a via penetrating at least a portion of the insulation layer and electrically connecting the first wiring pattern and the second wiring pattern; and
a protruding pattern extending into the insulation layer and having at least a portion embedded in the insulation layer, the protruding pattern disposed on the first wiring pattern and connected to the first wiring pattern, and positioned spaced apart from the via on the first wiring pattern.

13. The semiconductor package of claim 12, wherein:
the protruding pattern surrounds at least a portion of the via.

14. The semiconductor package of claim 12, further comprising:
a passivation layer disposed on the first wiring structure and having an opening that exposes at least a portion of the second wiring pattern.

15. The semiconductor package of claim 12, further comprising:
a second wiring structure spaced apart from the first wiring structure with the semiconductor chip and the encapsulant interposed therebetween.

16. The semiconductor package of claim 15, further comprising:
a conductive post connecting the first wiring structure and the second wiring structure and embedded in the encapsulant.

17. The semiconductor package of claim 15, further comprising:
a core substrate having a hole in which the semiconductor chip is disposed and the core substrate connecting the first wiring structure and the second wiring structure.

18. A semiconductor package comprising:
a first semiconductor package including a first wiring structure, a semiconductor chip disposed on the first wiring structure and connected to the first wiring structure, an encapsulant covering at least a portion of the semiconductor chip, and a second wiring structure disposed on the semiconductor chip and the encapsulant and connected to the first wiring structure;
a second semiconductor package disposed on the second wiring structure; and
a conductive bump disposed between the first semiconductor package and the second semiconductor package and connecting the first semiconductor package and the second semiconductor package,
wherein the second wiring structure includes
a first wiring pattern;
an insulation layer covering at least a portion of the first wiring pattern;
a second wiring pattern disposed on the insulation layer;
a via penetrating at least a portion of the insulation layer and electrically connecting the first wiring pattern and the second wiring pattern; and
a protruding pattern extending into the insulation layer and having at least a portion embedded in the insulation layer, the protruding pattern disposed on the first wiring pattern and connected to the first wiring pattern, and spaced apart from the via.

19. The semiconductor package of claim 18, wherein:
the protruding pattern surrounds at least a portion of the via,

20. The semiconductor package of claim 18, wherein:
the conductive bump is in contact with the second wiring pattern.
